(19) United States
(12) Patent Application Publication
(10) Pub. No.: US 2013/0213296 A1
(43) Pub. Date: Aug. 22, 2013

(54) METHOD FOR ACHIEVING SUSTAINED ANISOTROPIC CRYSTAL GROWTH ON THE SURFACE OF A MELT

(71) Applicants: Peter L. Kellerman, Essex, MA (US); Dawei Sun, Nashua, NH (US); Brian H. Mackintosh, Concord, MA (US)

(72) Inventors: Peter L. Kellerman, Essex, MA (US); Dawei Sun, Nashua, NH (US); Brian H. Mackintosh, Concord, MA (US)

(73) Assignee: VARIAN SEMICONDUCTOR EQUIPMENT ASSOCIATES, INC., Gloucester, MA (US)

(21) Appl. No.: 13/398,874

(22) Filed: Feb. 17, 2012

(51) Int. Cl. C30B 13/00

(52) U.S. Cl. 117/47

(57) ABSTRACT

A method of horizontal ribbon growth from a melt includes forming a leading edge of the ribbon using radiative cooling on a surface of the melt, drawing the ribbon in a first direction along the surface of the melt, and removing heat radiated from the melt in a region adjacent the leading edge of the ribbon at a heat removal rate that is greater than a heat flow through the melt into the ribbon.

### STATEMENT AS TO FEDERALLY SPONSORED RESEARCH OR DEVELOPMENT

The U.S. Government has a paid-up license in this invention and the right in limited circumstances to require the patent owner to license others on reasonable terms as provided for by the terms of contract number DE-EE0000595 awarded by the U.S. Department of Energy.

### BACKGROUND OF THE INVENTION

1. Field of the Invention

Embodiments of the invention relate to the field of substrate manufacturing. More particularly, the present invention relates to a method, system and structure for removing heat from a ribbon on a surface of a melt.

2. Discussion of Related Art

Silicon wafers or sheets may be used in, for example, the integrated circuit or solar cell industry. Demand for solar cells continues to increase as the demand for renewable energy sources increases. As these demands increase, one goal of the solar cell industry is to lower the cost/power ratio. There are two types of solar cells: silicon and thin film. The majority of solar cells are made from silicon wafers, such as single crystal silicon wafers. Currently, a major cost of a crystalline silicon solar cell is the wafer on which the solar cell is made. The efficiency of the solar cell, or the amount of power produced under standard illumination, is limited, in part, by the quality of this wafer. Any reduction in the cost of manufacturing a wafer without decreasing quality can lower the cost/power ratio and enable the wider availability of this clean energy technology.

The highest efficiency silicon solar cells may have an efficiency of greater than 20%. These are made using electronics-grade monocrystalline silicon wafers. Such wafers may be made by sawing thin slices from a monocrystalline silicon cylindrical boule grown using the Czochralski method. These slices may be less than 200 μm thick. As solar cells become thinner, the percent of silicon waste per cut increases. Limits inherent in ingot slicing technology, however, may hinder the ability to obtain thinner solar cells.

Another method of manufacturing wafers for solar cells is to pull a thin ribbon of silicon vertically from a melt and then allow the pulled silicon to cool and solidify into a sheet. The pull rate of this method may be limited to less than approximately 18 mm/minute. The removed latent heat during cooling and solidifying of the silicon must be removed along the vertical ribbon. This results in a large temperature gradient along the ribbon. This temperature gradient stresses the crystalline silicon ribbon and may result in poor quality multi-grain silicon. The width and thickness of the ribbon also may be limited due to this temperature gradient.

Producing sheets (or “ribbons”) horizontally from a melt by separation may be less expensive than silicon sliced from an ingot. Earlier attempts at such horizontal ribbon growth (HRG) have employed helium convective gas cooling to achieve the continuous surface growth needed for ribbon pulling. These early attempts have not met the goal of producing a reliable and rapidly drawn wide ribbon with uniform thickness that is “production worthy”. In view of the above, it will be appreciated that there is a need for an improved apparatus and method to produce horizontally grown silicon sheets from a melt.

### SUMMARY

This Summary is provided to introduce a selection of concepts in a simplified form that are further described below in the Detailed Description. This Summary is not intended to identify key features or essential features of the claimed subject matter, nor is it intended as an aid in determining the scope of the claimed subject matter.

In one embodiment, a method of horizontal ribbon growth from a melt includes forming a leading edge of the ribbon using radiative cooling on a surface of the melt. The method also includes drawing the leading edge in a first direction along the surface of the melt and removing heat radiated from the melt at a heat removal rate that is greater than a heat supply rate of heat flowing through the melt into the ribbon.

In another embodiment, a method of forming a ribbon of a first material from a melt includes providing a crystalline seed in the melt. The method further includes providing a heat flow through the melt q_{y}″b that is above the constitutional instability regime characterized by segregation of solutes during crystallization of the melt, setting a temperature T_{c} of a cold plate proximate a surface of the melt at a value below the melting temperature of the first material Tₘ such that the radiation heat flow from the melt surface q″ _{rad-liquid} is greater than the heat flow through the melt q_{y}″, and drawing the crystalline seed along a path orthogonal to a long axis of the cold plate.

### BRIEF DESCRIPTION OF THE DRAWINGS

FIG. 1 shows a scenario for horizontal ribbon growth.

FIG. 2 presents a graphical depiction of the calculated silicon growth behavior for different heat flow conditions.

FIG. 3 is a graph that depicts further details of growth regimes for growing silicon from a melt consistent with the present embodiments.

FIG. 4 depicts a scenario in which a crystalline silicon seed is located at a surface region of a silicon melt.

FIG. 5 schematically depicts a silicon growth scenario.

FIG. 6 shows a schematic depiction in which a silicon seed initiates anisotropic crystal growth consistent with the present embodiments.

FIGS. 7a and 7b depict simulations of silicon growth in which a cold plate is placed over a silicon melt.

FIGS. 8a and 8b present the results of further simulations of silicon growth.

FIGS. 9a-9d depict aspects of a procedure for controlling silicon ribbon width consistent with the present embodiments.

### DESCRIPTION OF EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, like numbers refer to like elements throughout.

To solve the deficiencies associated with the methods noted above, the present embodiments provide novel and inventive techniques and systems for horizontal melt growth of a crystalline material, in particular, a monocrystalline material. In various embodiments, methods for forming a sheet of monocrystalline silicon by horizontal melt growth are disclosed. However, in other embodiments, the methods disclosed herein may be applied to horizontal melt growth of germanium, as well as alloys of silicon, for example.

The disclosed methods are directed to forming long monocyrstalline sheets that are extracted from a melt by pulling in a generally horizontal direction. Such methods involve horizontal ribbon growth (HRG) in which a thin monocrystalline sheet of silicon or silicon alloys is drawn (pulled) along the surface region of a melt. A ribbon shape can be obtained by extended pulling such that the long direction of the ribbon is aligned along the pulling direction.

Prior efforts at developing HRG have included the use of radiative cooling to form crystalline sheets of silicon. It has been noted that the emissivity in solid silicon εₛ is about three times the emissivity in liquid silicon εₗ at the melting temperature of 1412° C. In this manner, heat is preferentially removed from the solid phase as opposed to the liquid phase, which forms a necessary condition for stable crystallization.

However, the large difference in emissivity εₛ−εₗ between solid and liquid silicon also makes it difficult to obtain rapid solidification of the melt surface. Accordingly, practical methods have not heretofore been developed for forming monocrystalline silicon sheets by horizontal melt growth. In the present embodiments, methods are disclosed for the first time in which the conditions for both stable crystalline growth and rapid growth may be achieved for horizontal extraction of solid silicon from a melt, such as HRG processing.

In particular, the present embodiments provide the ability to tune processing conditions within a process range that spans a transition between conditions for slow stable isotropic growth of a silicon crystal and conditions for highly anisotropic growth along a melt surface, the latter of which is needed to obtain sustained pulling of a crystalline sheet. The present authors have recognized that this transition depends upon a balance between heat flow within (through) the melt (necessary for stable crystal growth) and heat removal, which may take place by radiative heat transfer to a cold material placed proximate the melt surface.

It is known that stable crystal growth requires sufficient heat flow through the melt to overcome any constitutional instability caused by segregation of solutes that may occur during the freezing process. This condition can be expressed in terms of the temperature gradient dT/dy associated with a given heat flow along a direction y through the melt:

$$\frac{d T}{d y} > \frac{m {C}_{0} ( 1 - k ) v}{k D} \qquad ( 1 )$$

where C₀ is the solute concentration in the melt, D is the diffusion rate of solute in the melt, m is the slope of the liquidus line, k is the segregation coefficient, and υ is the growth rate. For example, for a typical silicon melt of electronics grade silicon, the concentration of iron (Fe) may be on the order of 10⁻⁸ Fe atoms/Si atom. For an Fe solute in a Si melt, k=8e−6, D˜1e−7 m²/s, and m˜1000 K/fraction. Accordingly, for a growth rate υ=6 μm/s, the required temperature gradient in the melt is ˜1 K/cm, which is equivalent to a heat conduction of ˜0.6 W/cm². Of course, other solutes may be present in the melt.

As detailed below, in various embodiments, a process window may be defined in which conditions for constitutionally stable crystal growth occur at the same time as conditions for highly anisotropic crystalline growth suitable for HRG. In particular, a process region of constitutional stability may be defined for a given materials system, as briefly discussed above with respect to Eq. (1). Within the process region of constitutional stability a region of anisotropic growth may be further defined as detailed in the discussion to follow. The overlap of these two regions defines a process window, which is termed a “growth regime,” where constitutionally stable anisotropic growth a crystalline layer from a melt can take place.

In a companion disclosure, “Apparatus for Achieving Sustained Anisotropic Crystal Growth on the Surface of a Silicon Melt” (Attorney Docket 1509V2011059, filed ______), incorporated by reference herein in its entirety, apparatus are detailed that implement methods disclosed herein.

The Figures and related discussion below focus on systems for silicon materials. However, it will be readily appreciated by those of ordinary skill that the present embodiments extend to other materials systems, and in particular to silicon-containing systems, such as alloys of silicon with germanium, carbon, and other elements including electrically active dopant elements. Other materials also may be used.

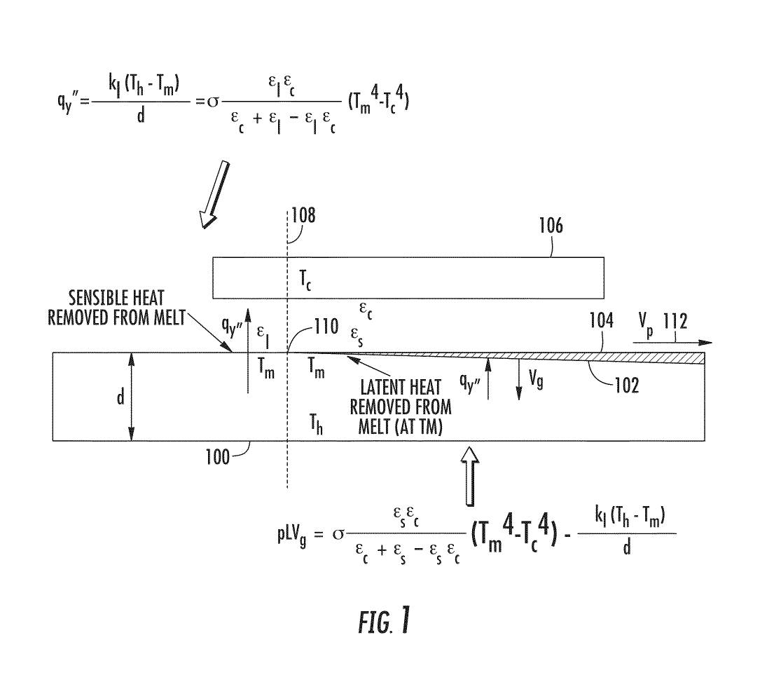

FIG. 1 illustrates an exemplary horizontal ribbon growth for a silicon melt 100 that includes a solid silicon ribbon 102 that may form in a surface 104. As illustrated, the ribbon 102 may be formed and pulled under a cold plate 106. A dotted line 108 delineates the leading edge 110 of the solid silicon where the silicon ribbon 102 has an interface with silicon melt 100 at the surface 104. To the right of the dotted line 108, heat flow through the melt q_{y}″ is conducted from the silicon melt 100 and into the solid silicon material of the silicon ribbon 102. A higher level of heat flow is radiated from the silicon ribbon 102 into the cold plate 106, based upon the emissivity εₛ of the silicon ribbon of =˜0.6. The difference between heat flow through the melt q_{y}″ and the heat radiated from the silicon ribbon 102 defines the latent heat of solidification for the silicon, which may be related to the velocity of growth V_{g} of the solid silicon phase provided that the radiation cooling is greater than the conductive heat flow as indicated in the following equation.

$$ρ {LV}_{g} = σ \frac{{ɛ}_{s} {ɛ}_{c}}{{ɛ}_{c} + {ɛ}_{s} - {ɛ}_{s} {ɛ}_{c}} ( {T}_{m}^{4} - {T}_{c}^{4} ) - \frac{{k}_{l} ( {T}_{h} - {T}_{m} )}{d} \qquad ( 2 )$$

where Tₕ is the temperature at the bottom of the melt, Tₘ is the equilibrium melting temperature, T_{c}, is the temperature of the cold plate, kₗ is the conductivity of the liquid (melt), d is the depth of melt, σ is the Stephan-Boltzmann constant, ρ is the density of the solid, L is the latent heat of fusion, and εₛ is the emissivity of the solid, and ε_{c} is the emissivity of the cold plate.

Just to the left of the dotted line 108 the same value of heat flow through the melt q_{y}″ takes place through the silicon melt 100. However, since no solidification is taking place, all this heat is radiated to the cold plate 106 based upon a lower emissivity of the silicon melt, which is approximately 0.2. In the region to the left of the dotted line under the cold plate 106, the relation between heat flow through the melt q_{y}″, melt temperature Tₘ, temperature at the bottom of the melt Tₕ, and cold plate temperature T_{c} is given by

$${q}_{y}^{″} = \frac{{k}_{l} ( {T}_{h} - {T}_{m} )}{d} = σ \frac{{ɛ}_{l} {ɛ}_{c}}{{ɛ}_{c} + {ɛ}_{l} - {ɛ}_{l} {ɛ}_{c}} ( {T}_{m}^{4} - {T}_{c}^{4} ) \qquad ( 3 )$$

where εₗ is the emissivity of the liquid melt.

The two different heat flow conditions that exist on opposite sides of the dotted line 108 can be related to one another because at the leading edge 110 the surface temperature of the silicon melt 100 is the same as the temperature of the solid silicon ribbon 102, which can be approximated to the equilibrium melting temperature Tₘ.

FIG. 2 presents a graphical depiction of the calculated silicon growth behavior for different heat flow conditions. In particular, the heat flow through the melt (q″_{y}) is plotted as a function of the temperature of a cold plate proximate the melt. In FIG. 2, the cold plate temperature T_{c} is expressed as a difference T_{c}−Tₘ between the temperature of the silicon melt and cold plate temperature. As discussed above, the heat flowing through a melt may be radiated from the surface to a cold plate, which may act as a heat sink to the radiation. The curves 202, 204, 206 show the calculated relationship between melt heat flow and cold plate temperature for different growth rates V_{g} of the solid. The calculations are based upon a solid emissivity εₛ of 0.6 and a liquid emissivity εₗ of 0.2, which approximate the properties of silicon at its melting temperature (1685 K, or 1412° C.). In particular, the growth rate V_{g} varies with different cold plate temperatures T_{c} and may be determined from Equation (2). As evident from equation (2), a relatively lower cold plate temperature, which is more effective in removing heat radiated from the silicon that a relatively higher cold plate temperature, results in a higher value of V_{g} for a given value of heat flow through the melt. In other words, a cooler cold plate is more effective than a hotter cold plate in removing heat radiated from the silicon proximate the cold plate.

Referring also to FIG. 2, the values of V_{g} illustrated in curves 202, 204 and 206 are applicable to the stable isotropic growth regime in which crystal growth may occur both vertically downward, as well as horizontally along the surface (but at very slow growth rates of ˜10 μm/s). That is, this growth behavior illustrated is for isotropic stable growth from a solid when heat is being removed from the solid. As illustrated, for a given heat flow through the melt q_{y}″ a lower cold plate temperature, that is, a larger value of T_{c}−Tₘ, produces a larger growth rate V_{g}, while for a given cold plate temperature a larger heat flow rate produces a smaller growth rate. Thus, the value of V_{g} is determined by a balance of the heat flow through the melt q_{y}″ which decreases the growth rate when increased, and the amount of heat absorbed by the cold plate, which increases with reduced T_{c}, thereby increasing the growth rate V_{g}.

FIG. 2 also includes a solid curve 208 which is a “sustained surface growth” line that marks conditions under which anisotropic crystal growth on the surface of a melt can occur. Thus, the solid curve 208 delineates the required relationship between the heat flow through the melt q_{y}″ and cold plate temperature T_{c} needed for the surface of the melt adjacent to the ribbon to independently freeze via radiation cooling. Referring again to FIG. 1, when the condition defined by solid curve 208 is satisfied, a solid silicon ribbon 102 can be extracted from the silicon melt 100, for example, by pulling or flowing the solid silicon ribbon to the right at a velocity Vₚ along the horizontal direction 112. The melt also may flow as the solid silicon ribbon is pulled or flowed. At the same time, the leading edge 110 remains at a fixed position (shown by dotted line 108) under the cold plate 106.

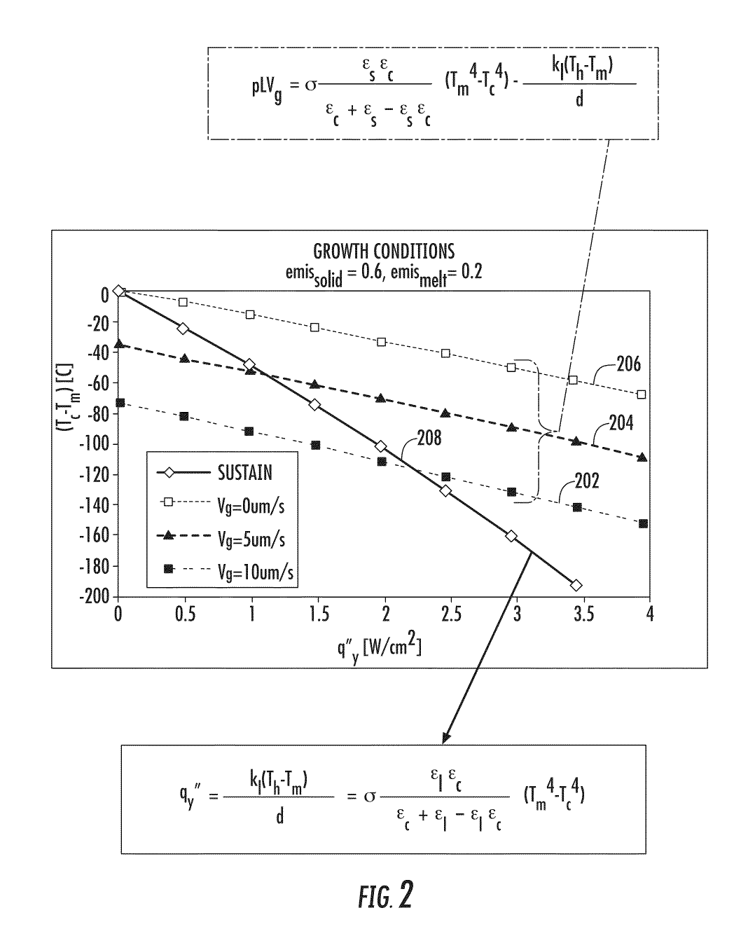

FIG. 3 is a graph that depicts further details of growth regimes for growing silicon from a melt consistent with the present embodiments. The axes of the graph of FIG. 3 are as in FIG. 2, while additional features that highlight aspects of the different growth regimes are shown. In FIG. 3 there are shown three different points A), B), and C), which correspond to different growth regimes 220, 222, and 224. At point A), T_{c}−Tₘ is −60° C., meaning that the temperature of a cold plate is maintained at 60° C. below the melting temperature of the material below the cold plate. In addition, the heat flow through the melt q_{y}″ is nearly 4 W/cm,² which leads to a condition in which no crystal growth takes place. It is to be noted that the curve 206 corresponds to a zero growth condition. Accordingly, any combination of heat flow through the melt q_{y}″ and T_{c}−Tₘ that lies above and to the right of curve 206 corresponds to a regime in which the crystal melts back, causing the ribbon and seed to thin at a rate given by

$${v}_{g} = \frac{{q}_{rad - solid}^{″} - {q}_{y}^{″}}{L \cdot ρ} < 0 \qquad ( 4 )$$

where q″_{rad-solid} is the radiation heat flow from the solid (that is, the crystalline seed).

This is further illustrated by FIG. 4, which depicts a scenario in which a crystalline silicon seed 402 is located at a surface region of a silicon melt 100. In this case the silicon seed 402 receives heat flow through the melt q_{y}″, which travels through the silicon melt 100 into the silicon seed 402. The silicon seed 402 radiates heat at a radiation heat flow from the solid q″_{rad-solid} towards a cold plate (not shown) that is less than q_{y}″. The net effect is that V_{g} is less than zero, meaning that a silicon seed 402 will shrink is size with time.

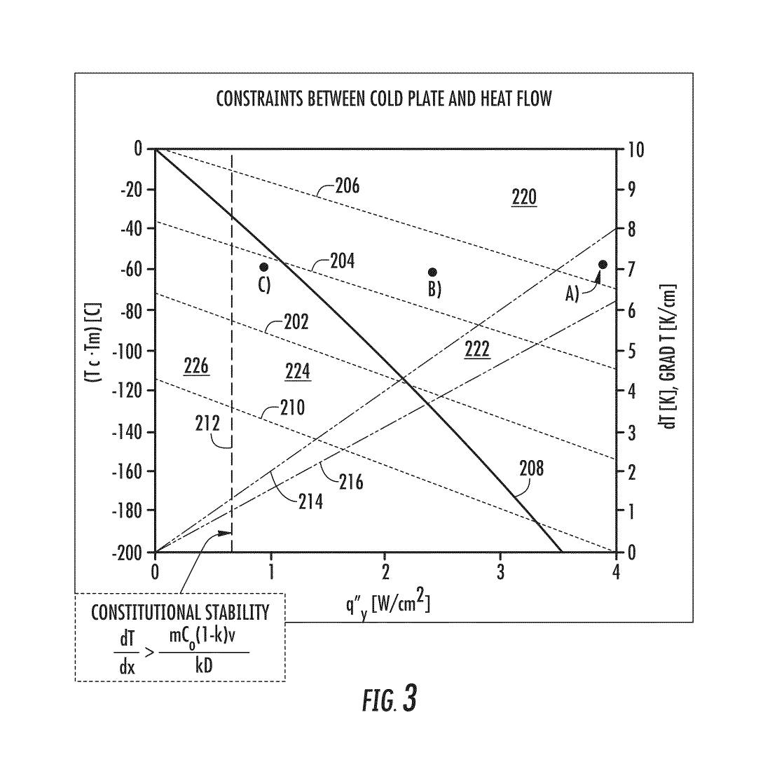

Turning to point B), which lies within the growth regime 222, this point corresponds to the same cold plate temperature T_{c} as point A illustrated in FIGS. 3 and 4. However, the heat flow through the melt q_{y}″ is substantially less, which results in a stable crystalline growth at a rate that is between the growth rates delineated by the curves 206 and 204, that is, a growth rate between 0 and 5 μm/s. FIG. 5 schematically depicts the growth scenario at point B), again shown in the context of a silicon seed 402 that lies at the surface of the silicon melt 100. This corresponds to the so-called slow growth regime in which stable isotropic crystal growth takes place. The radiation heat flow from the solid q″_{rad-solid} that is, from the silicon seed 402, is now greater than the heat flow through the silicon melt q_{y}″ and the radiation heat flow from the melt surface q″_{rad-liquid} is less than heat flow through the silicon melt q_{y}″. FIG. 5 illustrates that under these conditions the growth rate may be about 3 μm/s, resulting in formation of growth region 404 that may grow in an isotropic manner from the silicon seed 402. However, if the silicon seed 402 is drawn, for example, at 1 mm/s, no sustained pulling occurs in which a silicon sheet is drawn from the melt, and the isotropic growth rate is only 3 μm/s as illustrated.

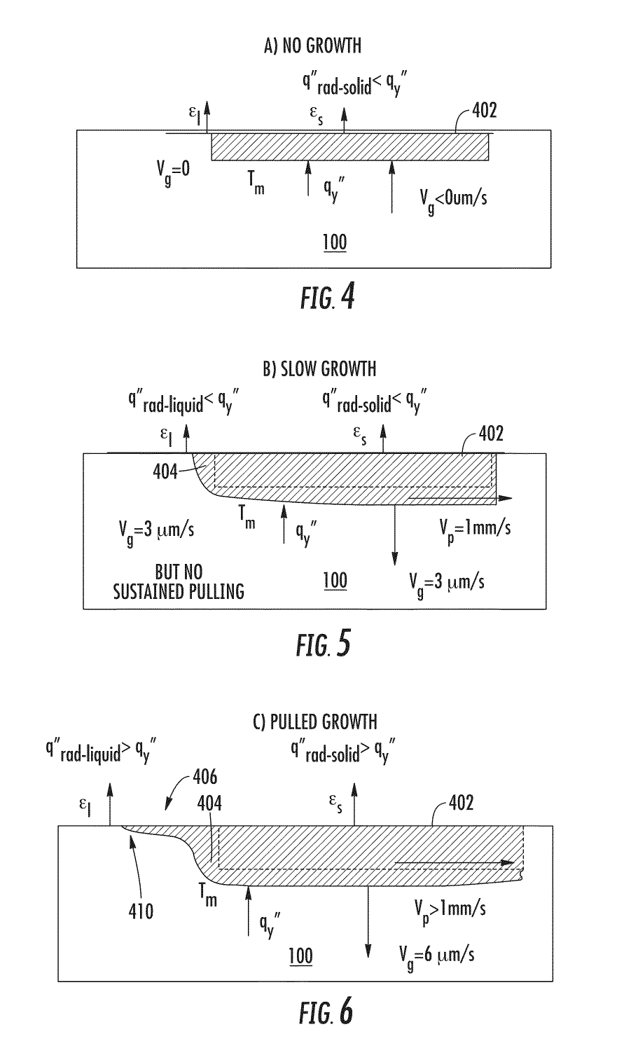

Turning now to point C) of FIG. 3, in this case the cold plate temperature T_{c} is also the same as that of points A) and B), while the heat flow through the silicon melt q_{y}″ is substantially less than that in point B), that is, 1 W/cm². Under these conditions, the growth regime corresponds to a regime that lies to the left of and below solid curve 208. As previously noted, this solid curve 208 delineates the sustained surface growth regime, and more particularly denotes a boundary of the sustained surface growth regime 224. Turning now to FIG. 6, there is shown a scenario in which a silicon seed 402 is pulled to the right under conditions specified by point C). Under these conditions, the radiation heat flow q″_{rad-solid} from the silicon seed 402 as well as the radiation heat flow from the silicon melt surface q″_{rad-liquid} are each greater than the heat flow through the silicon melt q_{y}″. As further illustrated in FIG. 6, the growth rate V_{g}, which corresponds to the isotropic growth rate is about 6 μm/s, since point C) lies between the curves 204 and 202, which correspond to growth rates of 5 μm/s and 10 μm/s, respectively. Moreover, when the silicon seed 402 is pulled to the right as illustrated, sustained anisotropic crystalline growth takes place at the surface of the silicon melt 100. Thus, a silicon sheet 406 forms at a leading edge 410, which remains at a fixed position while subjected to a pulling rate of 1 mm/s.

FIG. 3 depicts a further growth regime 226, which represents a regime of constitutional instability based on a growth rate of 6 μm/s as discussed above with respect to Equation (2). Thus, to the left of the line 212, which corresponds to the 0.6 W/cm², growth rates of 6 μm/s or greater may be constitutionally unstable given typical impurity concentrations that may be found in electronic silicon.

As illustrated in FIG. 3, the present inventors have identified for the first time the necessary conditions for anisotropic growth of a constitutionally stable silicon sheet by sustained pulling of a ribbon from a silicon melt in an HRG configuration. In particular, the necessary conditions can be defined by a two dimensional process window that balances heat flow through a silicon melt with a cold plate temperature that is set below the melting temperature of the silicon. In some embodiments, the process window can be expressed as the growth regime 224 and is bounded by regions of constitutional instability on the one hand, and regions of stable isotropic growth on the other hand.

In order to verify the validity of the analysis presented in FIGS. 3-6, finite element modeling using a commercially available heat transfer software package has been conducted. The modeling involves simulations accounting for heat transfer by conduction, convection, and radiation, including the materials emissivity of liquid and solid phases. FIGS. 7a and 7b depict simulations of silicon growth in which a cold plate 106 is placed over a silicon melt 100 that includes a silicon seed 702 at the surface of a silicon melt 100. The difference in silicon melt temperature and cold plate temperature Tₘ−T_{c} is set to 60° C., while the temperature at the bottom of a silicon melt (ΔTₘ) is set to 5 K above Tₘ. A two dimensional temperature profile of the silicon seed 702 and silicon melt 100 are shown at a first instance (FIG. 7a) when the silicon seed 702 is placed in the melt (0.03 sec) and at a second instance (FIG. 7b) about 70 seconds after the first instance. The silicon seed 702 is pulled in a horizontal direction toward the right at a velocity of 1 mm/s, which causes the left edge 706 of the silicon seed 702 to move about 70 mm to the right between the instances depicted in FIGS. 7a and 7b. Under the conditions simulated in FIGS. 7a, 7b, a portion 704 of the silicon seed 702 is observed to thicken from about 0.7 mm to about 1 mm, indicating isotropic growth. However, no sustained pulling is observed, indicating that the conditions for anisotropic growth have not been met. It is to be noted that the values of Tₘ−T_{c} and ΔTₘ correspond to the region 222 defined in FIG. 3, thereby confirming that this region results in isotropic silicon growth.

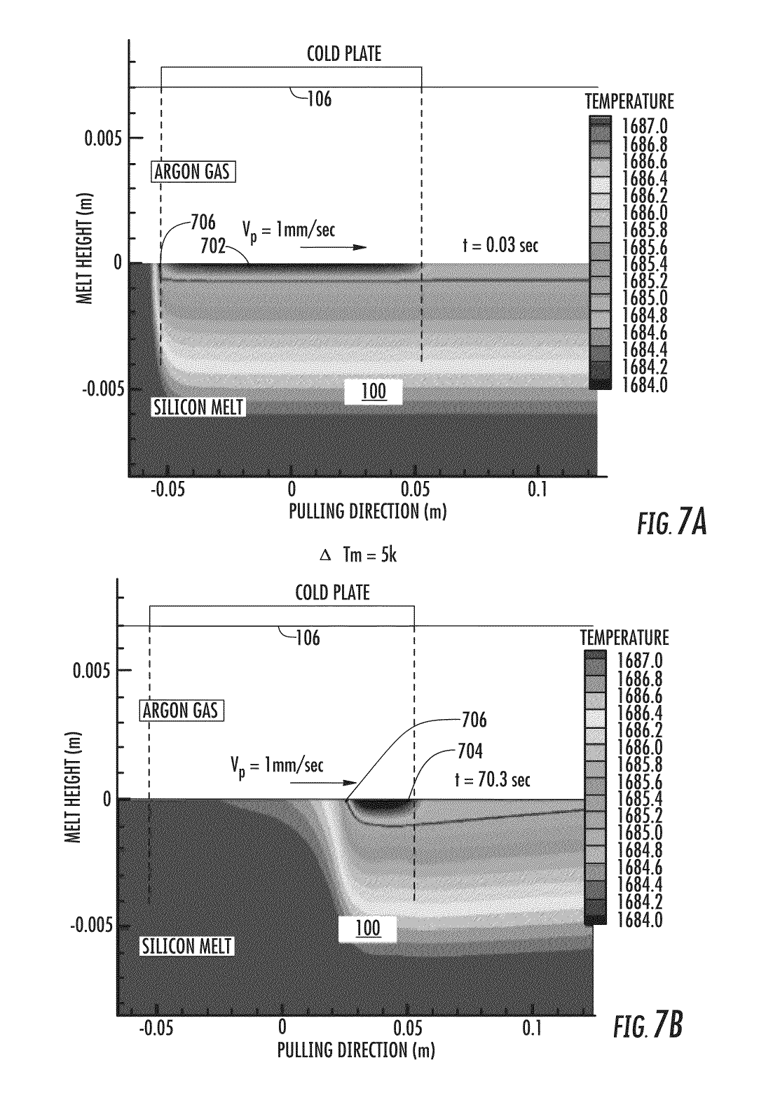

FIGS. 8a and 8b present the results of simulations in which all conditions are the same as in FIGS. 7a and 7b, save for ΔTₘ, which is set to 2 K. One effect of lowering ΔTₘ from 5 K to 2 K is to reduce the heat flow through the silicon melt q_{y}″ so that the process conditions now correspond to the growth regime 224 of FIG. 3. In FIG. 8a, a silicon seed 802 is shown shortly after being placed in the silicon melt 100. As confirmed by the results presented in FIG. 8b, after 101 seconds a thin silicon sheet 806 forms to the left of the original left edge 804 of the silicon melt 100. This thin silicon sheet 806 is indicative of anisotropic crystalline growth. Under the conditions shown, the leading edge 808 of the thin silicon sheet 806 remains stationary at a point P, thereby facilitating sustained (continuous) pulling of a silicon sheet (ribbon) at the 1 mm/s rate illustrated. After the silicon seed 802 passes a right edge 810 of the cold plate 106, steady state thickness of the thin silicon sheet 806 is reached.

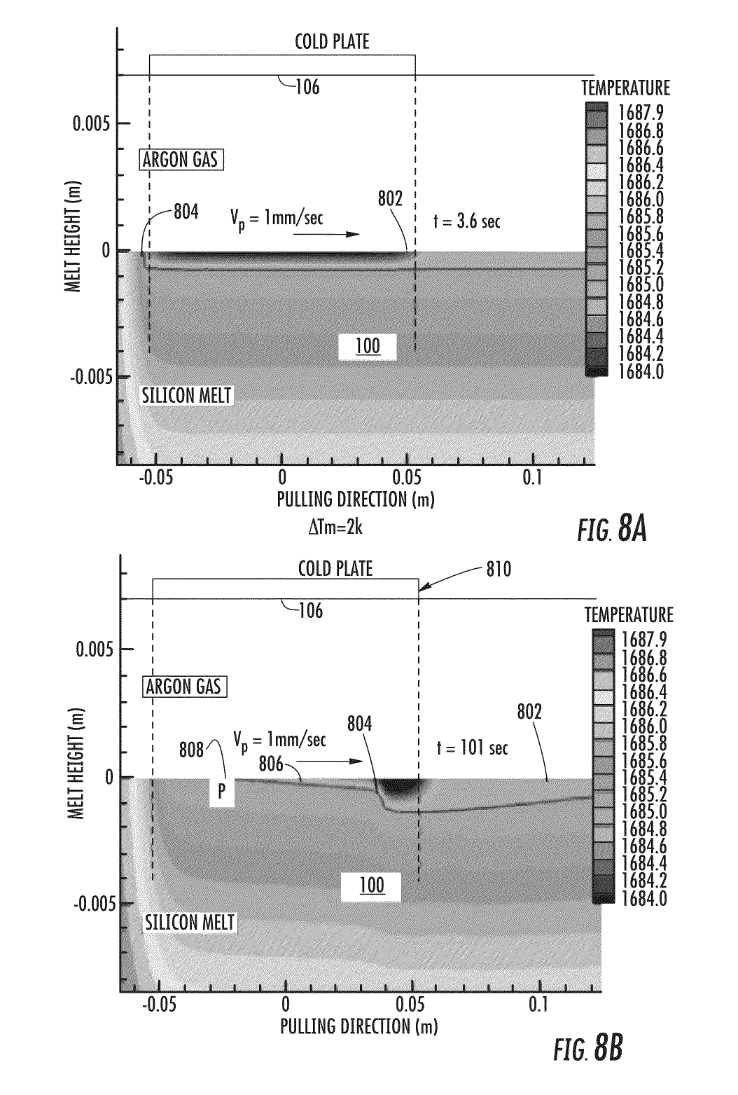

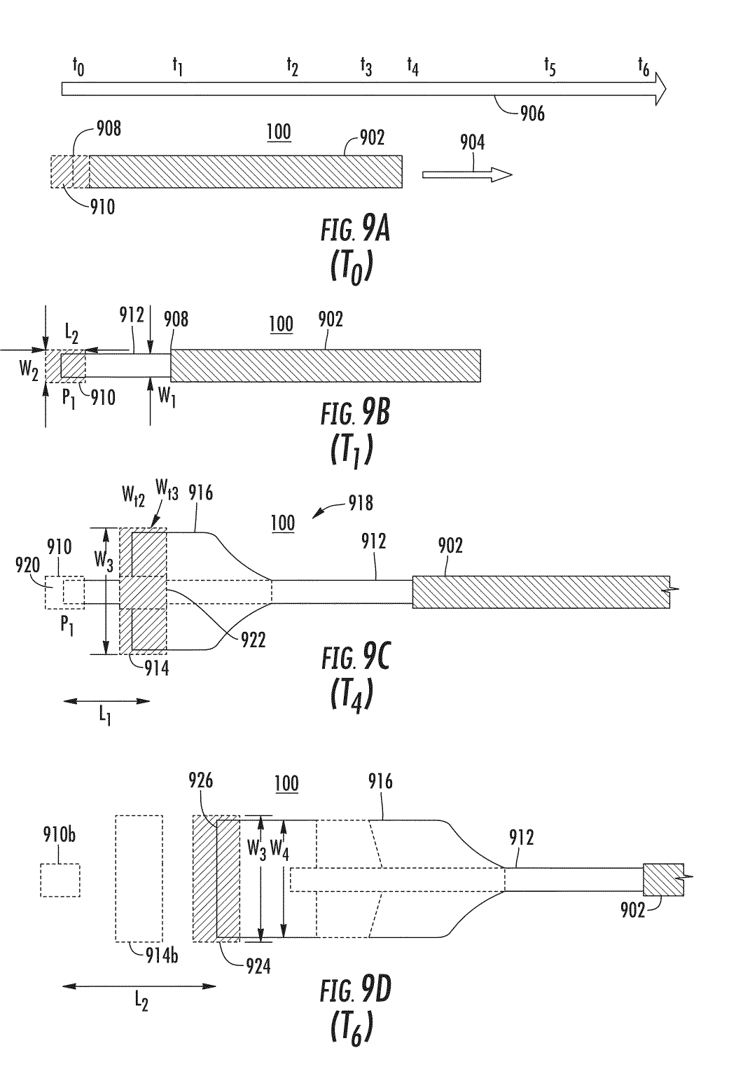

In various embodiments, the width of a silicon ribbon may be controlled by controlling the size of a cold plate used to receive radiation from the silicon melt or the size of the cold region produced by a cold plate. FIGS. 9a-9d depict aspects of a procedure for controlling silicon ribbon width consistent with the present embodiments. In the FIGS. 9a-9d a top plan view is shown that includes a view of a silicon seed 902 that is disposed on a surface region of a silicon melt 100. The FIGS. 9a-9d depict the formation of a silicon ribbon at various instances from T₀ to T₆. The silicon seed 902 is pulled in a direction 904 to the right as illustrated. A timeline 906 is also provided to show the position of the left edge 908 of the silicon seed as various instances. For example, FIG. 9a depicts the situation at t₀ where the left edge 908 is positioned under a cold region 910, which may be a cold plate as described above. Alternatively, the cold region may be a portion of a cold plate that is maintained at a desired temperature T_{c}, while other portions of the cold plate may be at higher temperatures, such as the temperature of the melt surface of the silicon melt 100. Accordingly, the width W₂ of the cold region 910, as well as the area of the cold region, W₂×L₂, may in general be less than the respective width and area of a cold plate placed proximate the silicon melt. In the cold regions indicated, the processing conditions, such as the difference in the temperature of the cold region 910 and the silicon melt temperature, as well as the heat flow through the silicon melt 100, are deemed to fall within the growth regime 224 of FIG. 3, where the temperature of the cold region 910 is T_{c} as described above regarding cold plate temperature. In this manner, the difference in temperature of the cold region 910 and silicon melt induces anisotropic crystalline growth when the silicon seed 902 is pulled along the silicon melt 100.

At T₀ the cold region 910 may be provided proximate the melt surface and above the left edge 908 of the silicon seed 902. As the silicon seed 902 is pulled to the right after time t₀ a silicon ribbon 912 forms by anisotropic growth. FIG. 9b depicts the situation at time t₁ where the left edge 908 has been pulled to the right with respect to the scenario of FIG. 9a. The width W₁ of the of the silicon ribbon 912 may be determined by the width W₂ of the cold region 910. For portions of the silicon melt 100 that are not under the cold region 910, heat flow through the melt is less, resulting in no anisotropic crystallization of the melt. As illustrated, the width W₁ of the silicon ribbon may be less than the width W₂ of cold region because the edges of the cold region 910 are less effective in absorbing heat from the silicon melt 100 as compared to the center of the cold region 910. It may be desirable to maintain a narrow width of the ribbon for a period of time to remove dislocations arising from the initial growth from the seed.

Subsequently, it may be desirable to increase the width of a silicon ribbon 912 beyond the width W₁ order to meet a target size for a substrate, for example. FIG. 9c depicts a scenario at a further instance in time t₄ in which the silicon ribbon 912 has been processed to increase its width. At the time t₄ a wide cold region 914 has been introduced proximate to the silicon melt 100. The wide cold region 914 has a width W₃ that is greater than W₂ and thereby produces a wide ribbon portion 916 that is integral with the silicon ribbon 912. The wide cold region 914 may have a second temperature T_{c2} such that the difference in T_{c2} and the silicon melt temperature, as well as the heat flow through the silicon melt 100, are deemed to fall within the growth regime 224 of FIG. 3. In other words, the difference in T_{c2} and Tₘ is such that the q″_{rad-liquid} is greater than the q_{y}″; and q_{y}″ has a value that is above that of a constitutional instability regime characterized by segregation of solutes during crystallization of the silicon melt 100. In particular, T_{c2} may be equal to T_{c2}.

The ribbon structure 918 illustrated in FIG. 9c may form in the following manner. As also illustrated in FIG. 9c, the leading edge 920 of the silicon ribbon 912 remains stationary at position P₁ under the cold region 910 for the reasons discussed above with respect to FIGS. 8a-8b. As the ribbon is pulled to the right, at a time t₂ the wide cold region 914, which is located at a distance L₁ from cold region 910 in the direction of pulling, is introduced proximate the silicon melt 100. The wide cold region 914 may have a variable width such that, at the time t₂ the wide cold region 914 only has a width Wₜ₂ which produces a cold region 922 as shown in FIG. 9c. In the example shown, the width Wₜ₂ is the same as W₂ and is increased over time up to time t₃. At time t₃ the width of the cold region is Wₜ₃ and is equivalent to the width W₃ in the example shown. It should be recognized that it is important to widen the cold region monotonically from W₂ to W₃ so that the crystal grows (i.e., widens) from a narrow ribbon outward, thereby enabling the crystal structure of the seed to maintained throughout the width of the ribbon and potentially allow growth of a dislocation-free single crystal ribbon. It should also be recognized that this widening process (between t₂ and t₃) may result in a widened sheet of non-uniform thickness. Thereafter the width Wₜ₃ (W₃) of wide cold region 914 is held constant up to time t₄ in FIG. 9c. During the time between t₃ and t₄ the width W₄ of the wide ribbon portion 916 may remain constant since Wₜ₃ is also held constant, resulting in the ribbon structure 918.

FIG. 9d illustrates the scenario for the ribbon structure 918 at an instance t₆. subsequent to t₄. At the instance shown in FIG. 9d, the cold region 910 and wide cold region 914 have been “turned off.” In other words a cold plate or similar device may be removed from the positions indicated by reference numbers 910b and 914b. In some embodiments, the cold plate(s) may be removed, while in other embodiments the temperature of the cold plate(s) may increase so that they no longer produce the effect of cold regions 910 and 914. In addition, in the scenario of FIG. 9d, a sustaining cold region 924 has been introduced proximate to the silicon melt 100 at a distance L₂ that is greater than L₁ from cold region 910 in the direction of pulling. In this example, the sustaining cold region 924 has a width W₃ similar to that of wide cold region 914 and thereby produces a uniform width of W₄ in the wide ribbon portion 916. The sustaining cold region 924 may have a third temperature T_{c3} such that the difference in T_{c2} and the silicon melt temperature, as well as the heat flow through the silicon melt 100, are deemed to fall within the growth regime 224 of FIG. 3. In some embodiments, T_{c3} may be set at T_{c} and/or T_{c2}. It should be noted that the sustaining cold region 924 has a constant width and uniform cooling effect, producing ribbon of uniform thickness. In some embodiments, the cold region 910 and wide cold region 914 are “turned off” at the same time as the sustaining cold region 924 is “turned on,” which may occur at an instance t₅ between the instances t₄ and t₆. Accordingly, as depicted in the scenario of FIG. 9d, any crystalline ribbon portions that lie to the left of the sustaining cold region 924 can subsequently heat up and remelt due to the lower heat flow conducted from the surface of the melt in those regions after the removal of cold regions 910, 914. This results in a new leading edge 926 of the wide ribbon portion 916. In alternative embodiments, the wide cold region 914 and sustaining cold region 924 are provided in a single location so that once the desired width W₄ is attained, the wide/sustaining cold region remains in place.

Subsequently, the sustaining cold region 924 remains in place and silicon is pulled to the right to produce a continuous silicon ribbon having a uniform thickness and the desired width W₄ until a desired length or ribbon is attained. The ribbon may be separated from the silicon melt 100 downstream of the sustaining cold region 924. Further processing to the ribbon may occur after this separation.

The methods described herein may be automated by, for example, tangibly embodying a program of instructions upon a computer readable storage media capable of being read by machine capable of executing the instructions. A general purpose computer is one example of such a machine. A non-limiting exemplary list of appropriate storage media well known in the art includes such devices as a readable or writeable CD, flash memory chips (e.g., thumb drives), various magnetic storage media, and the like.

The present invention is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present disclosure. Further, although the present disclosure has been described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the subject matter of the present disclosure should be construed in view of the full breadth and spirit of the present disclosure as described herein.

1. A method of horizontal ribbon growth from a melt, comprising:
forming a leading edge of the ribbon using radiative cooling on a surface of the melt;
drawing the ribbon in a first direction along the surface of the melt; and
removing heat radiated from the melt in a region adjacent the leading edge of the ribbon at a heat removal rate that is greater than a heat flow through the melt into the ribbon by setting a temperature of a cold plate proximate a surface of the melt at a value below the melting temperature of the first material; and
providing the heat flow through the melt at a heat flow rate that is above that of an instability regime characterized by segregation of solutes during crystallization of the melt, and is below a heat flow rate for stable isotropic crystal growth.

2. The method of claim 1, wherein the heat flow through the melt, given by q_{Y}″ is characterized according to
$${q}_{y}^{″} = \frac{{k}_{l} ( {T}_{h} - {T}_{m} )}{d} = σ \frac{{ɛ}_{l} {ɛ}_{c}}{{ɛ}_{c} + {ɛ}_{l} - {ɛ}_{l} {ɛ}_{c}} ( {T}_{m}^{4} - {T}_{c}^{4} )$$
wherein Tₕ is the temperature at the bottom of the melt, Tₘ is the equilibrium melting temperature, T_{c} is the temperature of the cold plate, kₗ is the conductivity of the liquid (melt), d is the depth of melt, σ is the Stephan-Boltzmann constant, ρ is the density of the solid, L is the latent heat of fusion, and εₛ is the emissivity of the solid, and ε_{c} is the emissivity of the cold plate.

3. The method of claim 1, wherein the heat flow through the melt is greater than 0.6 W/cm².

4. The method of claim 1, wherein the forming occurs in a first region of the melt and the ribbon has a first width along a second direction perpendicular to the first direction and further comprising:
drawing the ribbon along the first direction between the first region and a second region of the melt; and
growing the ribbon using radiative cooling in the second region to a second width in the second direction that is greater than the first width.

5. The method of claim 1, the melt comprising one of silicon, an alloy of silicon, and doped silicon.

6. A method of forming a ribbon of a first material from a melt, comprising:
providing a crystalline seed in the melt;
providing a heat flow through the melt q_{y}″ that is above that of a constitutional instability regime characterized by segregation of solutes during crystallization of the melt;
setting a temperature T_{c} of a cold region proximate a surface of the melt at a value below the melting temperature Tₘ of the first material such that radiation heat flow from the surface of the melt q″_{rad-liquid} is greater than the q_{y}″; and
drawing the crystalline seed from the cold region along a path.

7. The method of claim 6, wherein the q_{y}″ induces a temperature gradient along a direction dT/dx from a bottom of the melt to the surface of the melt such that
$$\frac{d T}{d x} > \frac{m {C}_{0} ( 1 - k ) v}{k D}$$
where C is a solute concentration in the melt, D is a diffusion rate of solute in the melt, k is a segregation coefficient, m is a slope of the liquidus line, and υ is a growth rate.

8. The method of claim 6, wherein the first material is one of silicon, an alloy of silicon, and doped silicon.

9. The method of claim 6, wherein emissivity from the crystalline seed is about 0.6 and emissivity from the melt is about 0.2.

10. The method of claim 6, wherein the q_{y}″ is 0.6 W/cm² or greater.

11. The method of claim 6, comprising:
setting the T_{c} at a level that is greater than 50° C. below the Tₘ; and
setting a temperature at a bottom of the melt that is between 1° C. and 3° C. greater than the Tₘ.

12. The method of claim 6, comprising:
providing a second cold region along the path and proximate the surface of the melt having a second temperature T_{c2} that is below the Tₘ such that the q″_{rad-liquid} is greater than the q_{y}″; and
expanding, monotonically, a width of a the second cold region.

13. The method of claim 12, wherein the T_{c2} is equal to the T_{c}.

14. A method of horizontal ribbon growth from a melt comprising:
forming a leading edge of the ribbon using radiative cooling on a surface of the melt in a first region, wherein the ribbon has a first width along a second direction;
drawing the ribbon along the surface of the melt in a first direction perpendicular to the second direction;
removing heat radiated from the melt in a region adjacent the leading edge of the ribbon at a heat removal rate that is greater than a heat flow through the melt into the ribbon;
providing the heat flow through the melt at a heat flow rate that is above that of an instability regime characterized by segregation of solutes during crystallization of the melt, and is below a heat flow rate for stable isotropic crystal growth;
transporting the ribbon along the first direction to a second region of the melt; and
growing the ribbon in the second direction using radiative cooling in the second region to a second width that is greater than the first width.

15. The method of claim 14, the melt comprising one of silicon, an alloy of silicon, and doped silicon.

16. The method of claim 14, wherein the heat flow through the melt, given by q_{Y}″ is characterized according to
$${q}_{y}^{″} = \frac{{k}_{l} ( {T}_{h} - {T}_{m} )}{d} = σ \frac{{ɛ}_{l} {ɛ}_{c}}{{ɛ}_{c} + {ɛ}_{l} - {ɛ}_{l} {ɛ}_{c}} ( {T}_{m}^{4} - {T}_{c}^{4} )$$
wherein Tₕ is the temperature at the bottom of the melt, Tₘ is the equilibrium melting temperature, T_{c} is the temperature of the cold plate, kₗ is the conductivity of the liquid (melt), d is the depth of melt, σ is the Stephan-Boltzmann constant, ρ is the density of the solid, L is the latent heat of fusion, and εₛ is the emissivity of the solid, and ε_{c} is the emissivity of the cold plate.
